(19) United States
(12) Patent Application Publication
(10) Pub. No.: US 2026/0293699 A1
(43) Pub. Date: Sep. 24, 2026

(54) CHIP PACKAGE AND METHOD FOR FORMING THE SAME

(71) Applicant: XINTEC INC., Taoyuan City (TW)

(72) Inventors: Po-Han LEE, Taipei City (TW); Wei-Ming CHIEN, Taoyuan City (TW); Tsang-Yu LIU, Zhubei City (TW)

(21) Appl. No.: 19/550,183

(22) Filed: Feb. 25, 2026

Related U.S. Application Data
(60) Provisional application No. 63/774,694, filed on Mar. 19, 2025.

(51) Int. Cl. H10W 70/05; H10W 70/65; H10W 70/68

(52) U.S. Cl. CPC H10W 70/05; H10W 70/65; H10W 70/68

(57) ABSTRACT

Chip packages and methods for forming the same are provided. The method includes providing a substrate having at least a chip region and a scribe-line region. The scribe-line region includes a first region surrounding the chip region and a second region surrounding the first region. A metallization layer is formed on the active surface of the substrate and includes a dielectric layer and first metal stacking layers in the dielectric layer. The first metal stacking layers are aligned with the first region. A first opening is formed in the metallization layer along the first region and surrounding the chip region. The first opening exposes the topmost layer surface of at least one of the first metal stacking layers and has different depths. A second opening is formed along the second region and surrounds the first region. The second opening passes through the metallization layer and extends into the substrate.

### CROSS REFERENCE TO RELATED APPLICATIONS

This application claims the benefit of U.S. Provisional Application No. 63/774,694, filed on Mar. 19, 2025, and entitled “CHIP PACKAGE AND METHOD FOR FORMING THE SAME”, the entirety of which is incorporated by reference herein.

### TECHNICAL FIELD

The invention relates to a packaging technology, and in particular it relates to a chip package and a method for forming the same.

### BACKBGOUND

Optoelectronic devices (e.g., image sensing devices) are widely used in electronic products such as digital cameras, digital video recorders mobile phones, and the like. The chip package process is an important step in the fabrication of electronic products. Chip packages not only protect sensing chips from outside environmental contaminants, but they also provide electrical connection paths between the electronic elements inside the sensing chip and exterior circuits.

Typically, individual chip packages are formed by singulation, using laser processing, dicing saw processing, or a combination thereof. However, the dielectric material layer (e.g., a low-k dielectric material) on wafers is usually brittle, lacking in mechanical strength, and it is sensitive to thermal stress. Therefore, this sort of singulation process can easily cause defects such as debris, cracks, rough sidewalls, and other types of defects in low-k dielectric materials. For example, even with a guard ring within the dielectric layer, it is still impossible to completely prevent cracks from extending into the chip region, thus failing to improve the yield of the chip package.

Therefore, there is a need for a novel method for forming chip packages that is capable of eliminating or mitigating the aforementioned problems.

### BRIEF SUMMARY

In accordance with some embodiments, a method for forming a chip package is provided. The method includes providing a substrate having at least a chip region and a scribe line region, wherein the scribe line region has a first region surrounding the chip region and a second region surrounding the first region. The method includes forming a metallization layer on the active surface of the substrate, wherein the metallization layer includes a dielectric layer and a plurality of first metal stacking layers disposed in the dielectric layer and aligned with the first region. The method includes forming a first opening along the first region and in the metallization layer to surround the chip region, wherein the first opening exposes the topmost layer surface of at least one first metal stacking layer and has different depths. The method includes forming a second opening along the second region to surround the first region, wherein the second opening extends through the metallization layer and into the substrate.

In accordance with some embodiments, a method for forming a chip package is provided. The method includes providing a first substrate and a second substrate, each having at least a chip region and a scribe line region, wherein the scribe line region has a first region surrounding the chip region and a second region surrounding the first region. The method includes forming a first metallization layer on the active surface of the first substrate and forming a second metallization layer on the active surface of the second substrate, wherein the first metallization layer and the second metallization layer each include a dielectric layer and a plurality of first metal stacking layers disposed in the dielectric layer and aligned with the first region. The method includes bonding the first metallization layer and the second metallization layer, so that the first substrate is stacked over the second substrate. The method includes forming a first opening along the first region of the first substrate and successively passing through the first substrate, the first metallization layer, and the second metallization layer to surround the chip region of the first substrate, wherein the first opening exposes the bottommost layer surface of the at least one of the plurality of the first metal stacking layer disposed in the first metallization layer.

In accordance with some embodiments, a chip package is provided. The chip package includes a substrate and a metallization layer. The substrate has at least a chip region and a peripheral region. The peripheral region has a first region surrounding the chip region. The metallization layer is located on the active surface of the substrate. The metallization layer includes a dielectric layer and a plurality of first metal stacking layers. The dielectric layer has an opening that extends along the first region to surround the chip region, and the plurality of first metal stacking layers is disposed in the dielectric layer and aligned with the first region. At least one of the plurality of first metal stacking layers is aligned with the opening.

In accordance with some embodiments, a chip package is provided. The chip package includes a first substrate, a second substrate, a first metallization layer, and a second metallization layer. The second substrate is bonded to and below the first substrate, and each has a chip region and a peripheral region. The peripheral region has a first region surrounding the chip region. The first and second metallization layers are disposed between the active surface of the first substrate and the active surface of the second substrate, so as to bond the first substrate to the second substrate. The first and second metallization layers each include a dielectric layer and a plurality of first metal stacking layers. The dielectric layer has an opening that is aligned with the first region, to surround the chip region of the first substrate. The opening successively passes through the first substrate, the first metallization layer, and the second metallization layer. The plurality of first metal stacking layers is disposed in the dielectric layer and aligned with the first region. At least one of the plurality of first metal stacking layers is aligned with the opening.

### BRIEF DESCRIPTION OF THE DRAWINGS

The present disclosure can be more fully understood by reading the subsequent detailed description and examples with references made to the accompanying drawings, wherein:

FIGS. 1A-1E are cross-sectional views of an exemplary method for forming a chip package according to some embodiments

FIG. 2 is a cross-sectional view of an exemplary chip package according to some embodiments.

FIGS. 3A-3E are cross-sectional views of an exemplary method for forming a chip package according to some embodiments.

FIG. 4 is a cross-sectional view of an exemplary chip package according to some embodiments.

FIGS. 5A-5E are cross-sectional views of an exemplary method for forming a chip package according to some embodiments.

FIG. 6 is a cross-sectional view of an exemplary chip package according to some embodiments.

FIG. 7 is a cross-sectional view of an exemplary chip package according to some embodiments.

FIG. 8 is a cross-sectional view of an exemplary chip package according to some embodiments.

FIG. 9 is a cross-sectional view of an exemplary chip package according to some embodiments.

### DETAILED DESCRIPTION

The making and using of the embodiments of the present disclosure are discussed in detail below. However, it should be noted that the embodiments provide many applicable inventive concepts that can be embodied in a variety of specific methods. The specific embodiments discussed are merely illustrative of specific methods to make and use the embodiments, and do not limit the scope of the disclosure. In addition, the present disclosure may repeat reference numbers and/or letters in the various embodiments. This repetition is for the purpose of simplicity and clarity, and does not imply any relationship between the different embodiments and/or configurations discussed. Moreover, when a first material layer is referred to as being on or overlying a second material layer, the first material layer may be in direct contact with the second material layer, or separated from the second material layer by one or more material layers.

A chip package according to some embodiments of the present disclosure may be used to package micro-electro-mechanical system chips. However, embodiments of the invention are not limited thereto. For example, the chip package of the embodiments of the invention may be implemented to package active or passive devices or electronic components of integrated circuits, such as digital or analog circuits. For example, the chip package is related to optoelectronic devices, micro-electro-mechanical systems (MEMS), biometric devices, micro fluidic systems, and physical sensors measuring changes to physical quantities such as heat, light, capacitance, pressure, and so on. In particular, a wafer-level package (WSP) process may optionally be used to package semiconductor chips, such as image-sensor elements, light-emitting diodes (LEDs), solar cells, RF circuits, accelerators, gyroscopes, fingerprint recognition devices, micro actuators, surface acoustic wave devices, pressure sensors, ink printer heads, and so on.

The above-mentioned wafer-level package process mainly means that after the packaging step is accomplished during the wafer stage, the wafer with chips is cut to obtain individual packages. However, in a specific embodiment, separated semiconductor chips may be redistributed on a carrier wafer and then packaged, which may also be referred to as a wafer-level package process. In addition, the above-mentioned wafer-level package process may also be adapted to form a chip package having multi-layer integrated circuit devices by a stack of a plurality of wafers having integrated circuits.

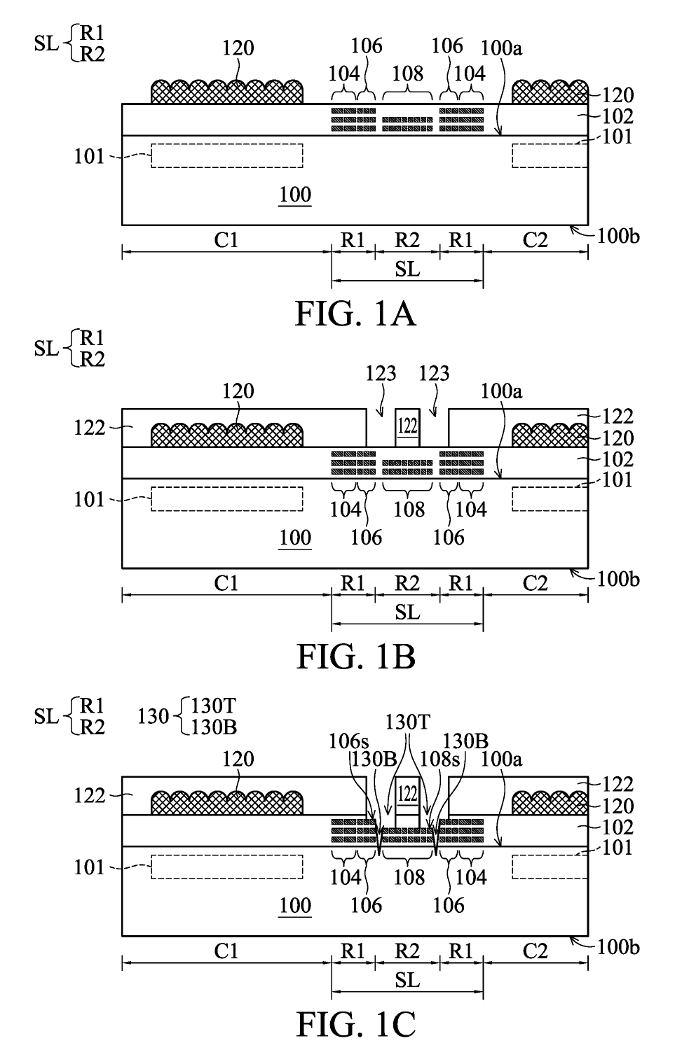

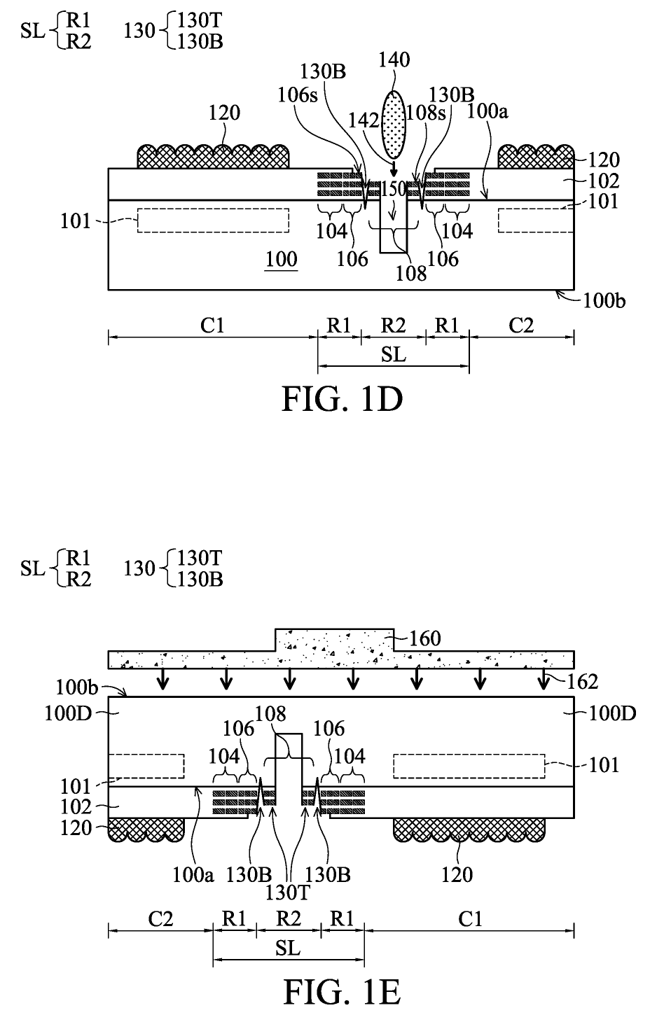

FIGS. 1A-1E illustrate cross-sectional views of a method for forming a chip package 10 according to some embodiments of the present disclosure. In some embodiments, the chip package 10 is implemented as having a front-side illumination (FSI) or back-side illumination (BSI) sensing device. However, in other embodiments, the chip package 10 may also be implemented as a chip stack having sensing devices or semiconductor devices and other semiconductor devices.

Referring to FIG. 1A, a substrate 100 is provided. In some embodiments, the substrate 100 is a wafer and is made of silicon or other semiconductor materials. The substrate 100 has an upper surface 100a (also referred to as the active surface) and an opposite lower surface 100b (also referred to as the non-active surface). The substrate 100 also has chip regions and a scribe line region surrounding these chip regions and separating adjacent chip regions. For the sake of simplicity, only a complete chip region C1 and an adjacent incomplete chip region C2 are depicted herein. The chip regions C1 and C2 are separated by a scribe line region SL. In some embodiments, the scribe line region SL has a first region R1 surrounding the chip regions C1 and C2 and a second region R2 surrounding the first region R1.

In some embodiments, each of the chip regions C1 and C2 of the substrate 100 includes a sensing region 101. Furthermore, the sensing region 101 includes a sensing device (not shown) adjacent to the upper surface 100a of the substrate 100. For example, the sensing region 101 includes an image sensing device or another suitable sensing device. In some embodiments, the sensing region 101 includes a device for sensing biometrics (e.g., a fingerprint recognition device), a device for sensing environmental characteristics (e.g., a temperature sensing device, a humidity sensing device, a pressure sensing device, a capacitance sensing device), or another suitable sensing device.

Next, in some embodiments, a metallization layer is formed on the upper surface 100a of the substrate 100. The metallization layer includes a dielectric layer 102 and interconnect structures (not shown) disposed in the dielectric layer 102, and metal stacking layers 104, 106, and 108. In some embodiments, the dielectric layer 102 includes an interlayer dielectric (ILD) layer, an inter-metal dielectric (IMD) layer, a passivation layer, or a combination thereof. For the sake of simplicity, only a flat layer is depicted herein. In some embodiments, the dielectric layer 102 includes an inorganic material, such as silicon oxide, silicon nitride, silicon oxynitride, metal oxides, or combinations thereof, or another suitable insulating material.

In some embodiments, the interconnect structures correspond to chip regions C1 and C2. In some embodiments, the sensing devices in the sensing region 101 are electrically connected via the interconnect structures (not shown) in the substrate 100 and the dielectric layer 102. Furthermore, one or more metal stacking layers 104 and one or more metal stacking layers 106 correspond to the first region R1 of the scribe line region SL, while one or more metal stacking layers 108 correspond to the second region R2 of the scribe line region SL. In some embodiments, the metal stacking layers 104 are implemented as guard rings surrounding the chip regions C1 and C2, while the metal stacking layers 106 are dummy metal stacking structures surrounding the guard rings. Therefore, the first region R1 is sometimes also referred to as a dummy zone. Furthermore, the metal stacking layers 108 may be implemented as test keys, other dummy structures, or combinations thereof.

The overlying and underlying metal layers in metal stacking layers 104, 106, and 108 may be electrically connected through vias (not shown) or electrically isolated from each other, depending on design requirements. Furthermore, the height of the upper surface (i.e., the surface or the top layer) of metal stacking layers 106 may be the same as or different than the height of the upper surface (i.e., the surface or the top layer) of metal stacking layers 108. For example, the upper surface of metal stacking layers 108 may be lower than the upper surface of metal stacking layers 106.

Next, in some embodiments, an optical component 120 (e.g., a microlens array, a color filter, a combination thereof, or another suitable optical component) is formed on the metallization layer above chip regions C1 and C2, respectively. For example, the optical component 120 is formed on the upper surface of dielectric layer 102 and aligned with sensing region 101.

Referring to FIG. 1B, in some embodiments, a mask pattern layer 122 (e.g., a photoresist, an adhesive film, or another suitable masking material) is formed on the upper surface 100a of the substrate 100 to cover the dielectric layer 102 and the optical component 120 above it. For example, the mask pattern layer 122 may be a photoresist pattern layer formed by a photolithography process. In some embodiments, the mask pattern layer 122 has a mask opening 123 extending along the first region R1 of the scribe line region SL to surround the chip regions C1 and C2. The mask opening 123 exposes the upper surface of the dielectric layer 102. For example, the mask opening 123 may correspond to a portion of the first region R1 and laterally extends onto a portion of the second region R2, and exposes the portion of the dielectric layer 102 overlying the metal stacking layers 106 and 108.

Referring to FIG. 1C, in some embodiments, after forming the mask pattern layer 122, an etching process (e.g., a dry etching process) is performed using the mask pattern layer 122 as an etch mask, so as to form the opening 130. In some embodiments, the etching process has selectivity to the metal materials of the metal stacking layers 106 and 108, so as to remove the dielectric layer 102 below the mask opening 123. Therefore, the metal stacking layers 106 and 108 themselves and the portion of the dielectric layer 102 covered by them are left after the etching process. Thus, the formed opening 130 exposes the topmost layer surface 106s of at least one of the metal stacking layers 106 and also exposes the topmost layer surface 108s of at least one of the metal stacking layers 108. As a result, the opening 130 has different depths. In the case where the topmost layer surface of the metal stacking layers 108 is lower than the topmost layer surface of the metal stacking layers 106, the maximum depth of opening 130 extends into the substrate 100 due to over-etching and is formed between metal stacking layers 106 and metal stacking layers 108. Furthermore, the minimum depth of opening 130 is formed at the exposed topmost layer surface 106s.

In some embodiments, the opening 130 includes an upper portion 130T and lower portions. The lower portions of opening 130 are spaces formed by removing the dielectric layer 102 formed between adjacent metal stacking layers. For the sake of simplicity, only a lower portion 130B formed between metal stacking layers 106 and metal stacking layers 108 is depicted herein. In some embodiments, the upper portion 130T of opening 130 exposes the topmost layer surface 106s of at least one of the metal stacking layers 106 and the topmost layer surface 108s of at least one of the metal stacking layers 108. Furthermore, the lower portion 130B of the opening 130 has a V-shaped cross-sectional profile, and the maximum depth of the opening 130 is at the lower portion 130B. In some embodiments, the aspect ratio of the V-shaped cross-sectional profile is in a range from about 2 to about 10, and the width ratio of the scribe line region SL to the V-shaped cross-sectional profile is in a range from about 1 to about 40.

Since the lower portion 130B of the opening 130 extends downward from the topmost layer surface 106s and penetrates the dielectric layer 102, a moat structure is formed. As a result, the lower portion 130B can effectively prevent stress, cracks, or other defects generated in the dielectric layer 102 during subsequent singulation processes from propagating or extending to the portion of the dielectric layer 102 over the chip regions C1 and C2.

Referring to FIG. 1D, a sawing process 142 (also referred to as a pre-sawing process) is performed on the structure shown in FIG. 1C. In some embodiments, the sawing process 142 is performed along a direction from the upper surface of the metallization layer toward the lower surface 100b of the substrate 100. Furthermore, along the second region R2, a sawing process 142 using a dicing saw 140 is sequentially performed on the mask pattern layer 122, the dielectric layer 102 of the metallization layer, and the underlying substrate 100 to form an opening 150. The opening 150 surrounds the first region R1 and extends through the dielectric layer 102 of the metallization layer into the substrate 100. Afterwards, the mask pattern layer 122 is removed to expose the dielectric layer 102 and the optical component 120. For example, the mask pattern layer 122 may be removed by a wet stripping process or other suitable stripping methods, so as to form the structure shown in FIG. 1E. In some embodiments, after removing the mask pattern layer 122, an optional clean process may be performed to remove any residues (if present).

Since the lower portion 130B of the opening 130 forms the moat structure, it can prevent the formation of debris, cracks, or other types of defects in the dielectric layer 102 during the sawing process 142, thereby improving the reliability of the chip package.

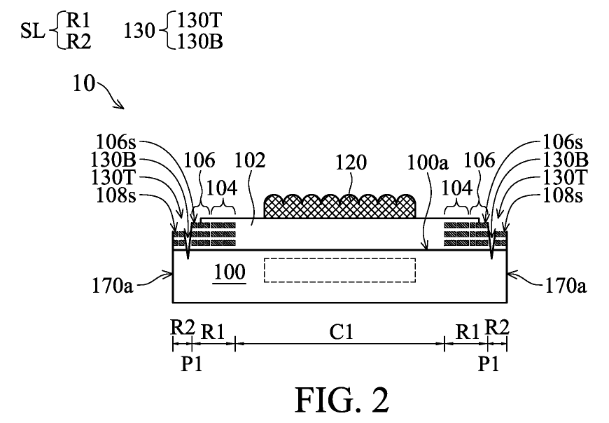

Referring to FIG. 1E, in some embodiments, after the sawing process 142, a thinning process (e.g., etching, milling, grinding, or polishing) is performed on the substrate 100 from its lower surface 100b until the opening 150 is exposed. For example, a grinding process 162 is performed on the lower surface 100b of the substrate 100 using a grinding wheel 160. After the grinding process 162, in addition to reducing the thickness of the substrate 100, adjacent chip regions C1 and C2 are separated from each other. As a result, an individual chip package 10 is completed, as shown in FIG. 2. Since the individual chip package 10 can be formed after the thinning process, no additional sawing process is required, thus reducing the manufacturing cost.

In some other embodiments, the thinning process (e.g., the grinding process 162) is performed first to reduce the thickness of the substrate 100. Afterwards, the sawing process 142 is performed. The sawed opening extends through the thinned substrate 100, so that the adjacent chip regions C1 and C2 are separated to complete the individual chip package 10.

Yet in some other embodiments, the sawing process 142 completely removes the dielectric layer 102 with the metal stacking layers 108 therein disposed over the second region R2. Furthermore, after the subsequent thinning process, a portion of the substrate 100 in the second region R2 is also removed.

FIG. 2 illustrates a cross-sectional view of an exemplary chip package 10 according to some embodiments. Elements in FIG. 2 that are the same as those in FIGS. 1A-1E are labeled with the same reference numbers as in FIGS. 1A-1E and are not described again for brevity. Referring to FIG. 2, the chip package 10 includes a substrate 100 and a metallization layer on the active surface 100a of the substrate 100. In some embodiments, the substrate 100 has a chip region C1 and a peripheral region P1. The peripheral region P1 is the remaining scribe line region SL after singulation (including the sawing process 142 and the grinding process 162, as shown in FIGS. 1D and 1E). The peripheral region P1 includes a first region R1 surrounding the chip region C1 and a second region R2 surrounding the first region R1.

In some embodiments, the metallization layer includes a dielectric layer 102 and metal stacking layers 104, 106, and 108 disposed in the dielectric layer 102. The dielectric layer 102 has an opening 130 that extends along the first region R1 to surround the chip region C1 and laterally extends onto the second region R2. In some embodiments, the opening 130 includes an upper portion 130T and a lower portion 130B. Furthermore, the metal stacking layers 104 and 106 are aligned with the first region R1, and one or more metal stacking layers 106 are aligned with the opening 130. The metal stacking layer 108 is aligned with the second region R2, and one or more metal stacking layers 108 are aligned with the opening 130. In some embodiments, the height of the upper surface (i.e., the topmost layer surface) of the metal stacking layer 106 is the same as or different than the height of the upper surface (i.e., the topmost layer surface) of the metal stacking layer 108. For example, the topmost layer surface of the metal stacking layer 108 may be lower than the topmost layer surface of the metal stacking layer 106.

In some embodiments, the upper portion 130T of the opening 130 exposes the topmost layer surface 106s of at least one of the metal stacking layers 106, and also exposes the topmost layer surface 108s of at least one of the metal stacking layers 108. In the cases where the topmost layer surface of the metal stacking layer 108 is lower than the topmost layer surface of the metal stacking layer 106, the upper portion 130T of the opening 130 has different depths. The lower portion 130B of the opening 130 is between the metal stacking layers 106 and 108. Furthermore, the lower portion 130B of the opening 130 has a V-shaped cross-sectional profile and extends into the substrate 100. In some embodiments, the aspect ratio of the V-shaped cross-sectional profile is in a range from about 2 to about 10.

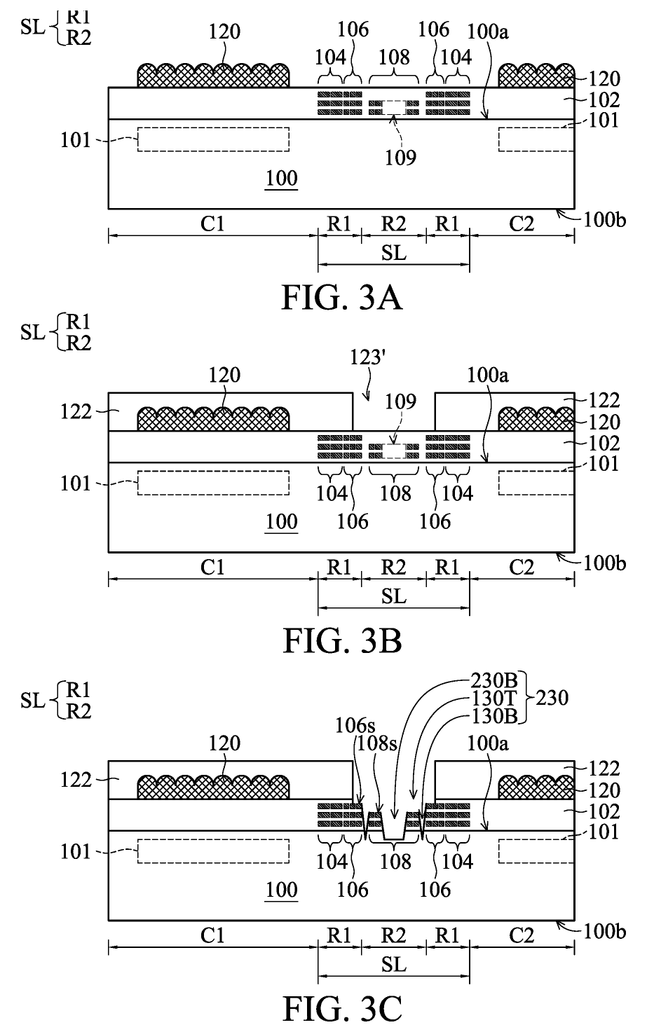

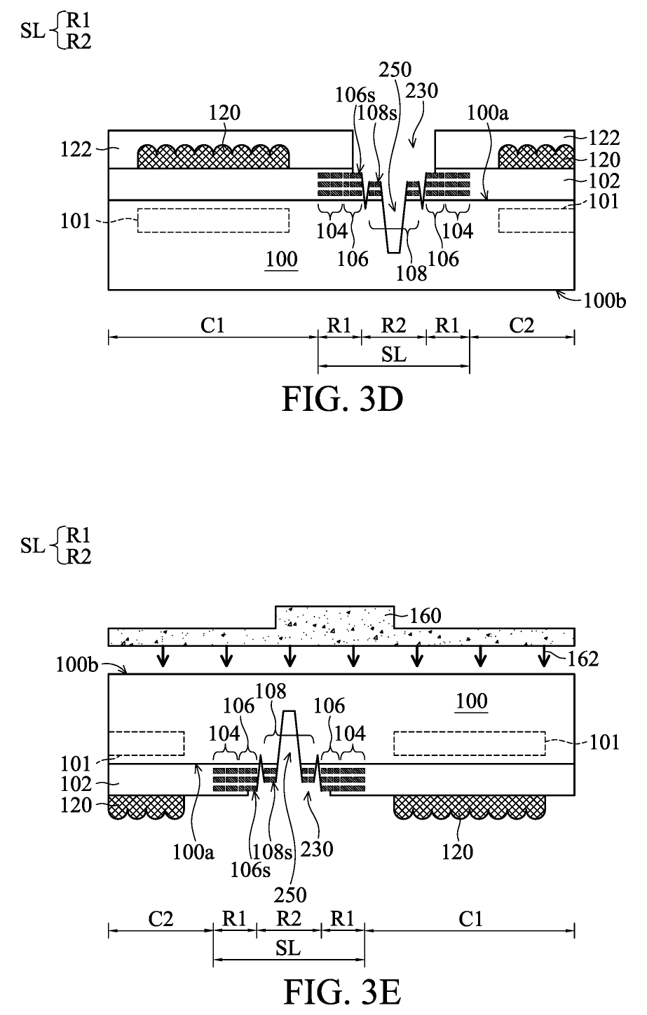

FIGS. 3A-3E illustrate cross-sectional views of a method for forming a chip package 10a according to some embodiments of the present disclosure. Elements in FIGS. 3A-3E that are the same as those in FIGS. 1A-1E are labeled with the same reference numbers as in FIGS. 1A-1E and are not described again for brevity. Referring to FIG. 3A, a substrate 100 is provided. The substrate 100 has an upper surface 100a (also referred to as an active surface) and an opposite lower surface 100b (also referred to as a non-active surface), and has chip regions and a scribe line region surrounding these chip regions and separating adjacent chip regions. For example, chip regions C1 and C2 are separated by the scribe line region SL. In some embodiments, the scribe line region SL has a first region R1 surrounding the chip regions C1 and C2 and a second region R2 surrounding the first region R1.

In some embodiments, the chip regions C1 and C2 of the substrate 100 each include a sensing region 101. Next, in some embodiments, a metallization layer is formed on the upper surface 100a of the substrate 100. The metallization layer includes a dielectric layer 102 and interconnect structures (not shown) and metal stacking layers 104, 106, and 108 disposed in the dielectric layer 102. In some embodiments, the dielectric layer 102 shown in FIG. 3A has a metal-free region 109 aligned with the second region R2 and adjacent to the metal stacking layers 108. In some other embodiments, the dielectric layer 102 aligned with the second region R2 does not have the metal stacking layers 108 or any metal layer, so that the metal-free region 109 overlaps with the second region R2.

Next, in some embodiments, an optical component 120 is correspondingly formed on the metallization layer above the chip regions C1 and C2. For example, the optical component 120 is formed on the upper surface of the dielectric layer 102 and aligned with the sensing region 101.

Referring to FIG. 3B, in some embodiments, a mask pattern layer 122 is formed on the upper surface 100a of the substrate 100 to cover the dielectric layer 102 and the overlying optical component 120. In some embodiments, the mask pattern layer 122 has a mask opening 123’ extending along the first region R1 of the scribe line region SL to surround the chip regions C1 and C2. The mask opening 123’ exposes the upper surface of the dielectric layer 102. For example, the mask opening 123’ corresponds to a portion of the first region R1 and laterally extends onto the entire second region R2, exposing a portion of the dielectric layer 102 disposed over the portion of the first region R1 and the portion of the entire second region R2.

Referring to FIG. 3C, in some embodiments, after forming the mask pattern layer 122, an etching process (e.g., a dry etching process) is performed using the mask pattern layer 122 as an etch mask to form an opening 230. In some embodiments, the etching process is employed to remove the dielectric layer 102 below the mask opening 123’. Therefore, the formed opening 230 exposes the topmost layer surface 106s of at least one of the metal stacking layers 106, and also exposes the topmost layer surface 108s of the metal stacking layer 108.

In some embodiments, the opening 230 includes an upper portion 130T and lower portions. The lower portions of opening 230 are the space formed by removing the dielectric layer 102 between adjacent metal stacking layers and the space formed by the dielectric layer 102 in the metal-free region 109. For the sake of simplicity, only the lower portion 130B between the metal stacking layers 106 and 108 and the lower portion 230B formed by removing the dielectric layer 102 in the metal-free region 109 are depicted herein. In some embodiments, the upper portion 130T of opening 230 exposes the topmost layer surface 106s of at least one of the metal stacking layers 106 and the topmost layer surface 108s of the metal stacking layers 108, while the lower portion 230B of opening 230 extends into the substrate 100. Furthermore, the lower portions 130B and 230B of opening 230 have a V-shaped cross-sectional profile and an inverted trapezoidal cross-sectional profile, respectively.

Referring to FIG. 3D, an etching process (e.g., a dry etching process) is performed on the structure shown in FIG. 3C. In some embodiments, the etching process is performed along a direction from the upper surface of the metallization layer toward the lower surface 100b of the substrate 100. Furthermore, an etching process is performed along the second region R2 on the substrate 100 below the lower portion 230B of the opening 230 to form an opening 250. The opening 250 surrounds the first region R1 and passes through the dielectric layer 102 of the metallization layer to extend into the substrate 100.

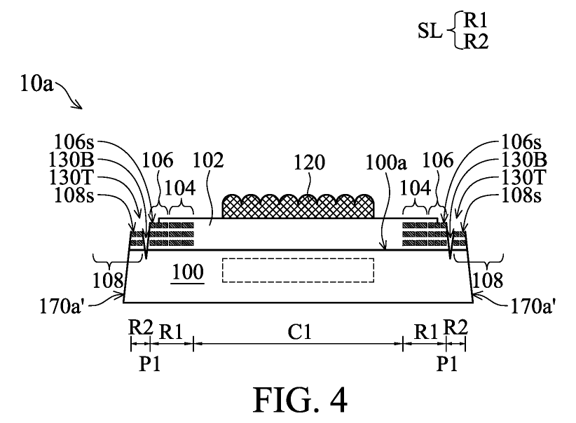

Referring to FIG. 3E, in some embodiments, the mask pattern layer 122 is removed to expose the dielectric layer 102 and the optical component 120. For example, the mask pattern layer 122 may be removed by a wet stripping process or other suitable stripping methods to form the structure shown in FIG. 3E. In some embodiments, after removing the mask pattern layer 122, an optional clean process is performed to remove any residues (if present). After the etching process, a thinning process is performed on the substrate 100 from its lower surface 100b until the opening 250 is exposed. For example, a grinding process 162 is performed on the lower surface 100b of the substrate 100 using a grinding wheel 160 to separate adjacent chip regions C1 and C2 from each other. This completes an individual chip package 10a, as shown in FIG. 4.

In some other embodiments, the thinning process (e.g., grinding process 162) is performed first to reduce the thickness of the substrate 100. Afterwards, the etching process is performed. The opening formed by the etching process extends through the thinned substrate 100, so as to separate adjacent chip regions C1 and C2 from each other to complete the individual chip package 10a. In some embodiments without the metal stacking layers 108, the etching process can completely remove the dielectric layer 102 disposed over the second region R2. Furthermore, after the subsequent thinning process, the portion of substrate 100 in the second region R2 is also removed.

FIG. 4 illustrates a cross-sectional view of an exemplary chip package 10a according to some embodiments. Elements in FIG. 4 that are the same as those in FIGS. 3A-3E are labeled with the same reference numbers as in FIGS. 3A-3E and are not described again for brevity. Referring to FIG. 4, the chip package 10a includes a substrate 100 and a metallization layer on the active surface 100a of the substrate 100. In some embodiments, the substrate 100 has a chip region C1 and a peripheral region P1. The peripheral region P1 is the remaining scribe line region SL after singulation (including the etching process and the grinding process 162, as shown in FIGS. 3D and 3E, respectively), and includes a first region R1 surrounding the chip region C1 and a second region R2 surrounding the first region R1.

In some embodiments, the metallization layer includes a dielectric layer 102 and metal stacking layers 104, 106, and 108 disposed in the dielectric layer 102. Similar to the chip package 10 shown in FIG. 2, the dielectric layer 102 in the chip package 10a has an opening (formed by the opening 230 (shown in FIG. 3E)) that includes an upper portion 130T and a lower portion 130B.

In some embodiments, the upper portion 130T of the opening exposes the topmost layer surface 106s of at least one of the metal stacking layers 106 and also exposes the topmost layer surface 108s of at least one of the metal stacking layers 108. The upper portion 130T of the opening has different depths. The lower portion 130B of the opening is formed between the metal stacking layers 106 and the metal stacking layers 108. Furthermore, the lower portion 130B of the opening has a V-shaped cross-sectional profile and extends into the substrate 100. In some embodiments, the aspect ratio of the V-shaped profile is in a range of about 2 to about 10.

The structure of the chip package 10a is similar to that of the chip package 10 shown in FIG. 2. However, the difference is that the chip package 10 has a substantially vertical sidewall surface 170a (as shown in FIG. 2), while the chip package 10a has tapered sidewalls 170a’. The vertical sidewall surface 170a of the chip package 10 is formed by a sawing process, while the tapered sidewall surface 170a’ of the chip package 10a is formed by an etching process.

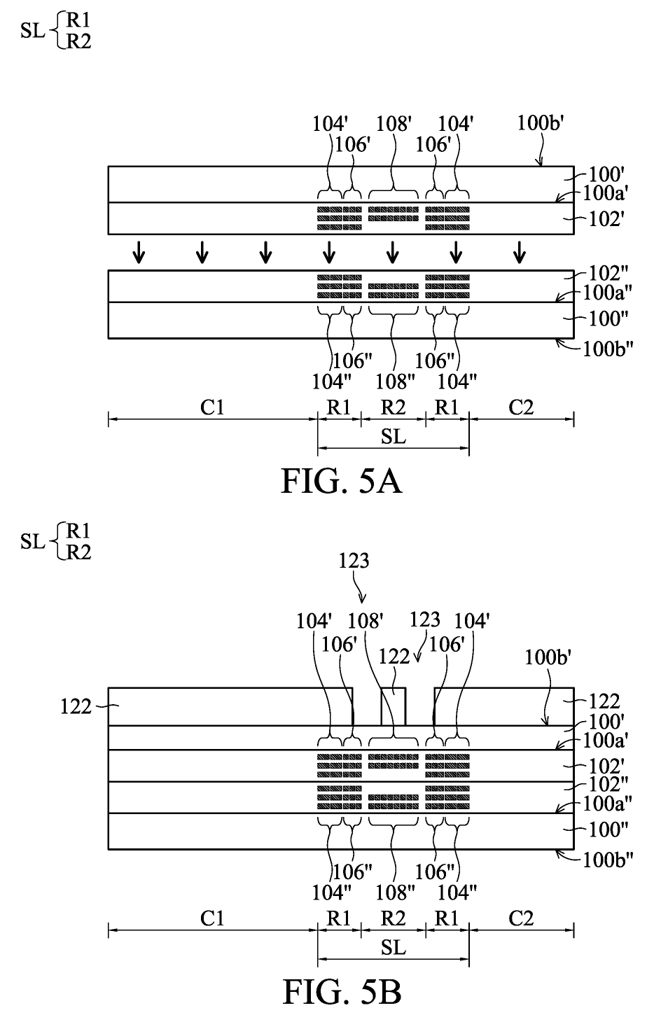

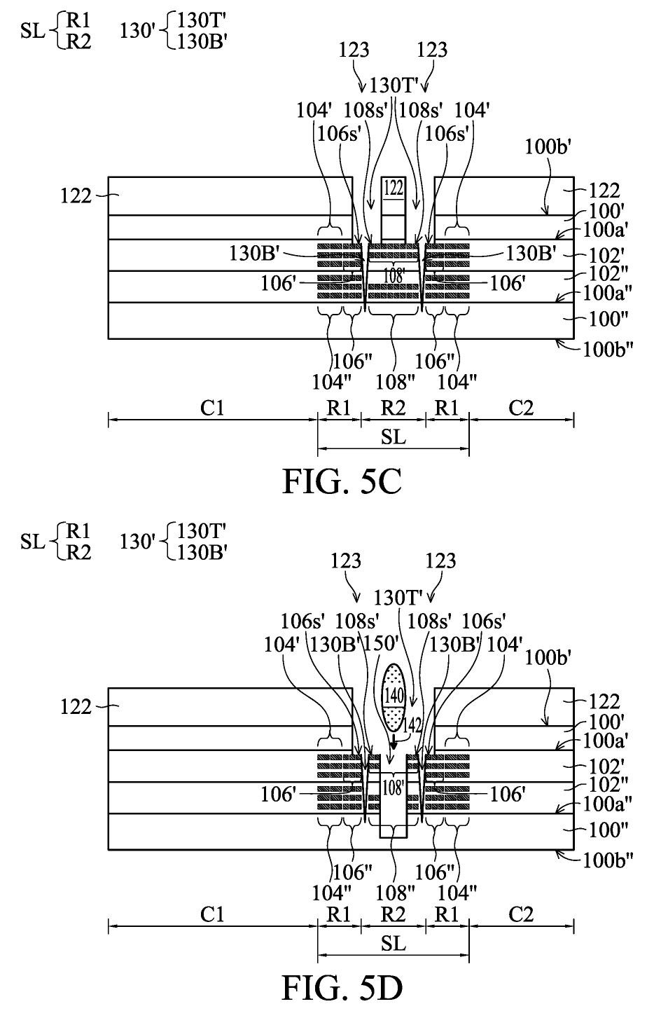

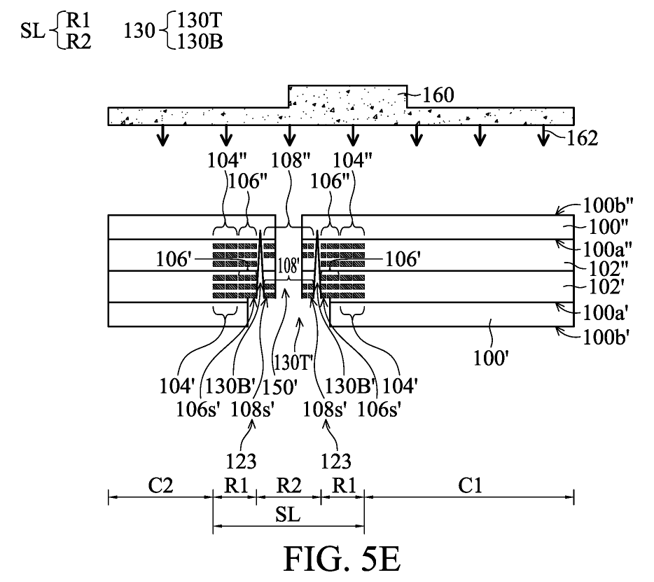

FIGS. 5A-5E illustrate cross-sectional views of a method for forming a chip package 20 according to some embodiments of the present disclosure. Elements in FIGS. 5A-5E that are the same as those in FIGS. 1A-1E are labeled with the same reference numbers as in FIGS. 1A-1E and are not described again for brevity. Referring to FIG. 5A, a first substrate 100’ and a second substrate 100” are provided. The first substrate 100’ and the second substrate 100” have upper surfaces 100a’ and 100a (also referred to as active surfaces) and lower surfaces 100b’ and 100b (also referred to as non-active surfaces), respectively. Furthermore, the first substrate 100’ and the second substrate 100” have chip regions and a dicing channel region surrounding these chip regions and separating adjacent chip regions. For example, chip regions C1 and C2 are separated by the scribe line region SL. In some embodiments, the scribe line region SL has a first region R1 surrounding chip regions C1 and C2 and a second region R2 surrounding the first region R1.

Next, in some embodiments, a first metallization layer is formed on the upper surface 100a’ of the first substrate 100’ and a second metallization layer is formed on the upper surface 100a” of the second substrate 100”. The first metallization layer includes a dielectric layer 102’ and an interconnect structure (not shown) and metal stacking layers 104’, 106’, and 108’ disposed in the dielectric layer 102’, while the second metallization layer includes a dielectric layer 102” and an interconnect structure (not shown) and metal stacking layers 104”, 106”, and 108” disposed in the dielectric layer 102”.

Next, the first metallization layer and the second metallization layer are bonded together, so that the first substrate 100’ is stacked over the second substrate 100”, as shown in FIG. 5B. Referring again to FIG. 5B, in some embodiments, a thinning process is performed on the lower surface 100b’ of the first substrate 100’. Afterwards, a mask pattern layer 122 is formed on the lower surface 100b’ of the first substrate 100’. For example, the mask pattern layer 122 may be a photoresist pattern layer. In some embodiments, the mask pattern layer 122 has a mask opening 123 extending along a first region R1 of the scribe line region SL to surround the chip regions C1 and C2. The mask opening 123 exposes the lower surface 100b’ of the first substrate 100’. For example, the mask opening 123 corresponds to a portion of the first region R1 and laterally extends onto a portion of the second region R2, and exposes the portion of the first substrate 100’ corresponding to the metal stacking layers 106 and 108.

Referring to FIG. 5C, in some embodiments, after forming the mask pattern layer 122, an etching process (e.g., a dry etching process) is performed using the mask pattern layer 122 as an etch mask to form an opening 130’. In some embodiments, the etching process has selectivity to the metal materials of the metal stacking layers 106’ and 108’. Therefore, after the etching process, the opening 130’ successively passes through the first substrate 100’, the first metallization layer 102’, and the second metallization layer 102”, surrounds the C1 and C2 chip regions, and extends into the second substrate 100”. Meanwhile, the metal stacking layers 106’ and 108’ themselves and the portions of the dielectric layers 102’ and 102” that are covered by them are left. As a result, the opening 130’ has different depths. The formed opening 130’ exposes the bottommost layer surface 106s’ of at least one of the metal stacking layers 106’, and also exposes the bottommost layer surface 108s’ of at least one of the metal stacking layers 108’.

In some embodiments, the opening 130’ includes an upper portion 130T’ and lower portions. The lower portions of the opening 130’ are spaces formed by removing dielectric layers 102’ and 102” between adjacent metal stacking layers. For the sake of simplicity, only a lower portion 130B’ formed between the metal stacking layers 106’ and 106” and the metal stacking layers 108’ and 108” corresponding to them is depicted herein. In some embodiments, the upper portion 130T’ of the opening 130’ exposes the bottommost layer surface 106s’ of at least one of the metal stacking layers 106’ and the bottommost layer surface 108s’ of at least one of the metal stacking layers 108. Furthermore, the lower portion 130B’ of the opening 130’ has a V-shaped cross-sectional profile, and the maximum depth of the opening 130’ is at the lower portion 130B’ of the opening 130’.

Since the lower portion 130B’ of the opening 130’ extends downward from the bottommost layer surface 106s’ to penetrate the dielectric layers 102’ and 102”, a moat structure may be formed to prevent stress, cracks or other defects generated in the dielectric layers 102’ and 102” during the subsequent singulation processes from propagating or extending to the dielectric layers 102’ and 102” over the chip regions C1 and C2.

Referring to FIG. 5D, a sawing process 142 is performed on the structure shown in FIG. 5C. In some embodiments, the sawing process 142 is performed along a direction from the upper surface of the dielectric layer 102’ toward the lower surface 100b” of the substrate 100”. Furthermore, a sawing process 142 is successively performed on the mask pattern layer 122, the first substrate 100’, the dielectric layer 102’, and the dielectric layer 102” using a dicing saw 140 along the second region R2 to form an opening 150’. The opening 150’ surrounds the first region R1 and extends through the dielectric layers 102’ and 102” into the substrate 100”. Afterwards, the mask pattern layer 122 is removed to expose the lower surface 100b’ of the first substrate 100’. For example, the mask pattern layer 122 may be removed by a wet stripping process or other suitable stripping methods, so as to form the structure shown in FIG. 5E. In some embodiments, after removing the mask pattern layer 122, an optional clean process is performed to remove any residue (if present).

Since the lower portion 130B’ of the opening 130’ forms a moat structure, it can prevent the formation of debris, cracks, or other types of defects in the dielectric layers 102’ and 102” during the sawing process 142, thereby improving the reliability of the chip package.

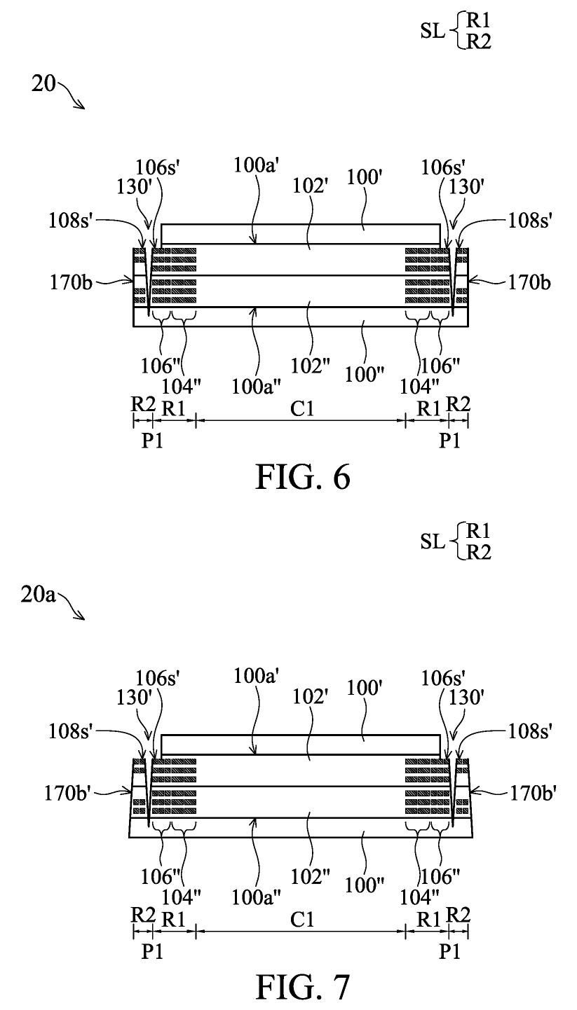

Referring to FIG. 5E, in some embodiments, after the sawing process 142, a thinning process (e.g., etching, milling, grinding, or polishing) is performed on the substrate 100 from the lower surface 100b” of the second substrate 100” until the opening 150’ is exposed. For example, a grinding process 162 is performed on the lower surface 100b” of the second substrate 100” using a grinding wheel 160 to separate adjacent chip regions C1 and C2 from each other. This completes an individual chip package 20, as shown in FIG. 6.

In some other embodiments, the thinning process (e.g., grinding process 162) is performed first to reduce the thickness of the second substrate 100”. Afterwards, the sawing process 142 is performed. The sawed opening extends through the thinned second substrate 100”, so that adjacent chip regions C1 and C2 are separated to complete the individual chip package 20.

Yet in some other embodiments, the sawing process 142 completely removes the dielectric layer 102 with the metal stacking layer 108 therein disposed over the second region R2. Furthermore, after the subsequent thinning processes, the portion of the substrate 100 in the second region R2 is also removed.

Yet in some other embodiments, each of the dielectric layers 102’ and 102” shown in FIG. 5A has a metal-free region aligned with the second region R2 and adjacent to the metal stacking layer 108. In some other embodiments, the dielectric layer 102 aligned with the second region R2 does not have the metal stacking layers 108 or any metal layer, so that the metal-free region 109 overlaps with the second region R2. In these cases, an etching process may be used instead of the sawing process 142 to separate adjacent chip regions C1 and C2 from each other.

FIG. 6 illustrates a cross-sectional view of an exemplary chip package 20 according to some embodiments. Elements in FIG. 6 that are the same as those in FIGS. 5A-5E are labeled with the same reference numbers as in FIGS. 5A-5E and are not described again for brevity. Referring to FIG. 6, the chip package 20 includes a first substrate 100’, a second substrate 100” and first and second metallization layers respectively formed on the upper surface 100a’ of the first substrate 100’ and the upper surface 100a” of the second substrate 100”. In some embodiments, the first substrate 100’ is bonded to the underlying second substrate 100”. The first substrate 100’ and the second substrate 100” each have a chip region C1 and a peripheral region P1. The peripheral region P1 is the remaining scribe line region SL after singulation (including the sawing process 142 and the grinding process 162, as shown in FIGS. 5D and 5E). The peripheral region P1 includes a first region R1 surrounding the chip region C1 and a second region R2 surrounding the first region R1.

In some embodiments, the first metallization layer includes a dielectric layer 102’ and metal stacking layers 108’ (as shown in FIG. 5E), 106’, and 104’ disposed in the dielectric layer 102’, while the second metallization layer includes a dielectric layer 102” and metal stacking layers 108” (as shown in FIG. 5E), 106”, and 104” disposed in the dielectric layer 102”. The dielectric layer 102” has an opening 130’ aligned with the first region R1 to surround the chip region C1, and laterally extending onto the second region R2. In some embodiments, the opening 130’ successively passes through the first substrate 100’, the dielectric layer 102’, and the dielectric layer 102”. Furthermore, the opening 130’ includes an upper portion 130T’ and a lower portion 130B’. Furthermore, metal stacking layers 104’, 104”, 106’, and 106” are aligned with the first region R1, and one or more metal stacking layers 106’ and one or more metal stacking layers 106” are aligned with the opening 130’. Metal stacking layers 108’ and 108” are aligned with the second region R2, and one or more metal stacking layers 108’ and one or more metal stacking layers 108” are aligned with the opening 130’.

In some embodiments, the upper portion 130T’ of the opening 130’ exposes the bottommost layer surface 106s’ of at least one of the metal stacking layers 106’, and also exposes the bottommost layer surface 108s’ of at least one of the metal stacking layers 108’. The lower portion 130B’ of the opening 130’ is formed between the metal stacking layers 106’ and 106” and the corresponding metal stacking layers 108’ and 108”. Furthermore, the lower portion 130B’ of the opening 130’ has a V-shaped cross-sectional profile and extends into the second substrate 100”.

FIG. 7 illustrates a cross-sectional view of an exemplary chip package 20a according to some embodiments. Elements in FIG. 7 that are the same as those in FIG. 6 are labeled with the same reference numbers as in FIG. 6 and are not described again for brevity. Referring to FIG. 7, the structure of the chip package 20a is similar to that of the chip package 20 shown in FIG. 6. However, the difference is that the chip package 20 has a substantially vertical sidewall surface 170b (as shown in FIG. 6), while the chip package 20a has a tapered sidewall 170b’. The vertical sidewall surface 170b of the chip package 20 is formed by a sawing process, while the tapered sidewall surface 170b’ of the chip package 20a is formed by an etching process.

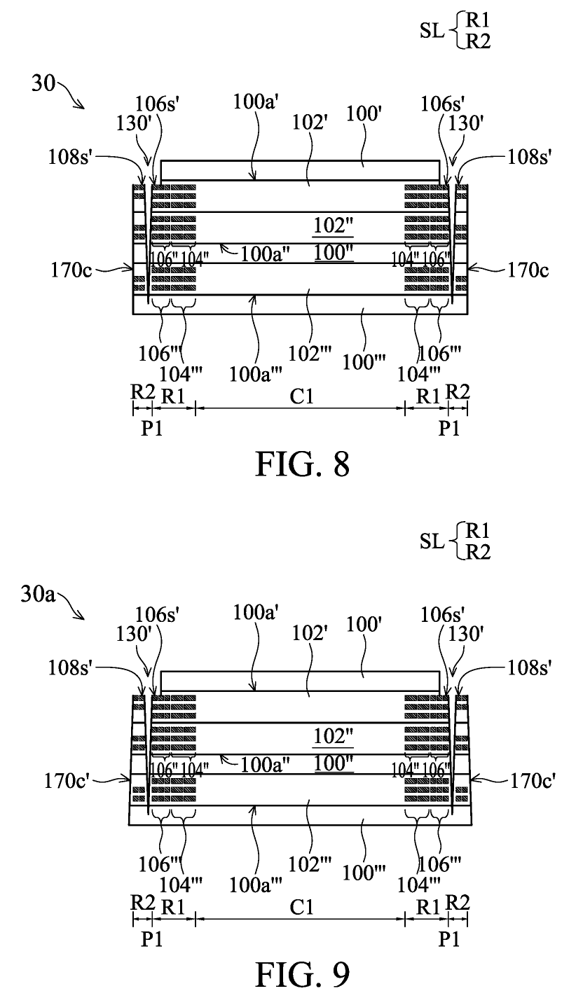

FIG. 8 illustrates a cross-sectional view of an exemplary chip package 30 according to some embodiments. Elements in FIG. 8 that are the same as those in FIG. 6 are labeled with the same reference numbers as in FIG. 6 and are not described again for brevity. Referring to FIG. 8, the structure of the chip package 30 is similar to that of the chip package 20 shown in FIG. 6. However, the difference is that the chip package 30 further includes a third substrate 100’’’ and a third metallization layer disposed on an upper surface 100a’’’ of the third substrate 100’’’. The third substrate 100’’’ is bonded to the lower surface of the second substrate 100” opposite to its upper surface 100a’’’ via the third metallization layer. As a result, the second substrate 100” and the first substrate 100’ are successively stacked over the third substrate 100’’’. Similarly, the third substrate 100’’’ has a chip region C1 and a peripheral region P1. Furthermore, the peripheral region P1 includes a first region R1 surrounding the chip region C1 and a second region R2 surrounding the first region R1.

In some embodiments, the third metallization layer includes a dielectric layer 102’’’, metal stacking layers 104’’’ and 106’’’ disposed in the dielectric layer 102’’’ and aligned with the first region R1, and metal stacking layers disposed in the dielectric layer 102’’’ and aligned with the second region R2. The dielectric layer 102’ has an opening 130’ aligned with the first region R1, surrounding the chip region C1, and laterally extending onto the second region R2. In some embodiments, the opening 130’ successively passes through the first substrate 100’, the dielectric layer 102’, the dielectric layer 102’’’, the second substrate 100”, and the dielectric layer 102’’’ and extends into the third substrate 100’’’. Furthermore, the metal stacking layers 104’, 104”, 106’, and 106” are aligned with the first region R1, and one or more metal stacking layers 106’ and one or more metal stacking layers 106” are aligned with the opening 130’. One or more metal stacking layers aligned with the second region R2 are aligned with the opening 130’.

Similar to the opening 130’ shown in FIG. 6, the opening 130’ shown in FIG. 7 also includes an upper portion and a lower portion. The upper portion exposes the bottommost layer surface 106s’ of at least one of the metal stacking layers 106’, and also exposes the bottommost layer surface 108s’ of at least one of the metal stacking layers 108’. The lower portion is formed between the metal stacking layers 106’ and 106” and the metal stacking layer corresponding to the second region R2. Furthermore, the lower portion has a V-shaped cross-sectional profile and extends into the third substrate 100’’’.

FIG. 9 illustrates a cross-sectional view of an exemplary chip package 30a according to some embodiments. Elements in FIG. 9 that are the same as those in FIG. 8 are labeled with the same reference numbers as in FIG. 8 and are not described again for brevity. Referring to FIG. 9, the structure of the chip package 30a is similar to that of the chip package 30 shown in FIG. 8. However, the difference is that the chip package 30 has a substantially vertical sidewall surface 170c (as shown in FIG. 8), while the chip package 30a has a tapered sidewall 170c’. The vertical sidewall surface 170c of the chip package 30 is formed by a sawing process, while the tapered sidewall surface 170c’ of the chip package 30a is formed by an etching process.

According to the foregoing embodiments, an opening having different depths and extending along the edges of the chip region is formed in the dielectric layer corresponding to and above the scribe line region by using an etching process. Furthermore, the upper portion of the opening exposes the topmost or bottommost layer surface of the metal stacking layer in the dielectric layer above the scribe line region, while the lower portion of the opening penetrates the dielectric layer. As a result, the opening forms a moat structure to prevent the formation of debris, cracks, or other types of defects in the dielectric layer due to mechanical or thermal stress during the sawing process. Therefore, the reliability of the chip package is improved. According to the foregoing embodiments, an individual chip package can be formed by performing a pre-sawing process followed by a thinning process. Alternatively, the dielectric layer corresponding to and above the scribe line region has a metal-free region, so that the individual chip package can be formed by performing an etching process followed by a thinning process. As a result, no additional sawing process is required for singulation, thereby simplifying the process and reducing manufacturing costs.

While the disclosure has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for forming a chip package, comprising:
providing a substrate having at least a chip region and a scribe line region, wherein the scribe line region has a first region surrounding the chip region and a second region surrounding the first region;
forming a metallization layer on an active surface of the substrate, wherein the metallization layer comprises:
a dielectric layer; and
a plurality of first metal stacking layers disposed in the dielectric layer and aligned with the first region;
forming a first opening along the first region and in the metallization layer to surround the chip region, wherein the first opening exposes a topmost layer surface of at least one of the plurality of first metal stacking layers and has different depths; and
forming a second opening along the second region to surround the first region, wherein the second opening extends through the metallization layer and into the substrate.

2. The method as claimed in claim 1, further comprising:
performing a thinning process on an opposing surface of the active surface of the substrate until the second opening is exposed.

3. The method as claimed in claim 1, wherein forming the first opening comprises:
forming a mask pattern layer on the metallization layer above the chip region and the scribe line region, wherein the mask pattern layer has a mask opening corresponding to a portion of the first region and laterally extending onto a portion of the second region; and
performing a dry etching process to form the first opening.

4. The method as claimed in claim 1, wherein a maximum depth of the first opening extends into the substrate.

5. The method as claimed in claim 1, wherein the metallization layer further comprises:
a plurality of second metal stacking layers disposed in the dielectric layer and aligned with the second region, wherein the first opening exposes a topmost layer surface of at least one of the plurality of second metal stacking layers.

6. The method as claimed in claim 5, wherein the topmost layer surface of the at least one of the second metal stacking layers is lower than the topmost layer surface of the at least one of the first metal stacking layers.

7. The method as claimed in claim 5, wherein the second opening is formed by a sawing process.

8. The method as claimed in claim 5, wherein the first opening includes:
an upper portion exposing the topmost layer surface of the at least one of the plurality of first metal stacking layers and the topmost layer surface of the at least one of the plurality of second metal stacking layers; and
a lower portion having a V-shaped cross-sectional profile.

9. The method as claimed in claim 8, wherein an aspect ratio of the V-shaped cross-sectional profile is in a range of 2 to 10, and a width ratio of the scribe line region to the V-shaped cross-sectional profile is in a range of 1 to 40.

10. The method as claimed in claim 1, wherein the dielectric layer has a metal-free region therein and is aligned with the second region.

11. The method as claimed in claim 10, wherein the second opening is formed by performing a dry etching process successively on the dielectric layer at the metal-free region and the substrate below the metal-free regio.

12. A method for forming a chip package, comprising:
providing a first substrate and a second substrate, each having at least a chip region and a scribe line region, wherein the scribe line region has a first region surrounding the chip region and a second region surrounding the first region;
forming a first metallization layer on an active surface of the first substrate and forming a second metallization layer on an active surface of the second substrate, wherein the first metallization layer and the second metallization layer each comprises:
a dielectric layer; and
a plurality of first metal stacking layers disposed in the dielectric layer and aligned with the first region;
bonding the first metallization layer and the second metallization layer, so that the first substrate is stacked over the second substrate; and
forming a first opening along the first region of the first substrate and successively passing through the first substrate, the first metallization layer, and the second metallization layer to surround the chip region of the first substrate,
wherein the first opening exposes a bottommost layer surface of the at least one of the plurality of first metal stacking layers disposed in the first metallization layer.

13. The method as claimed in claim 12, further comprising:
forming a second opening along the second region, wherein the second opening successively extends through the first metallization layer and the second metallization layer, and downward into the second substrate; and
performing a thinning process on an opposing surface of the active surface of the second substrate until the second opening is exposed.

14. The method as claimed in claim 12, wherein the second opening is formed by a sawing process or a dry etching process.

15. The method as claimed in claim 11, further comprising:
before forming the first opening, performing a thinning process on an opposing surface of the active surface of the first substrate, wherein the first opening is formed by a dry etching process.

16. The method as claimed in claim 12, wherein the first metallization layer and the second metallization layer each further comprises:
a plurality of second metal stacking layers disposed in the dielectric layer and aligned with the second region.

17. A chip package, comprising:
a substrate having at least a chip region and a peripheral region, wherein the peripheral region includes a first region surrounding the chip region; and
a metallization layer disposed on the active surface of the substrate, wherein the metallization layer includes:
a dielectric layer having an opening extending along the first region to surround the chip region; and
a plurality of first metal stacking layers disposed in the dielectric layer and aligned with the first region, wherein at least one of the plurality of first metal stacking layers is aligned with the opening.

18. The chip package as claimed in claim 17, wherein the peripheral region further comprises:
a second region surrounding the first region, wherein the metallization layer further comprises:
a plurality of second metal stacking layers disposed in the dielectric layer and aligned with the second region, wherein the opening laterally extends onto the second region and is aligned with at least one of the plurality of second metal stacking layers.

19. The chip package as claimed in claim 18, wherein the topmost layer surface of the at least one of the plurality of second metal stacking layers is lower than the topmost layer surface of the at least one of the plurality of first metal stacking layers.

20. The chip package as claimed in claim 18, wherein the opening comprises:
an upper portion exposing a topmost layer surface of the at least one of the plurality of first metal stacking layers and a topmost layer surface of the at least one of the plurality of second metal stacking layers; and
a lower portion having a V-shaped cross-sectional profile.

21. The chip package as claimed in claim 17, wherein the opening comprises:
an upper portion exposing a topmost layer surface of the at least one of the plurality of first metal stacking layers; and
a lower portion having a V-shaped cross-sectional profile.

22. The chip package as claimed in claim 21, wherein the aspect ratio of the V-shaped cross-sectional profile is in a range of 2 to 10.

23. A chip package, comprising:
a first substrate and a second substrate bonded to and below the first substrate, each having a chip region and a peripheral region, wherein the peripheral region includes a first region surrounding the chip region; and
a first metallization layer and a second metallization layer disposed between the active surface of the first substrate and the active surface of the second substrate, so as to bond the first substrate to the second substrate, wherein each of the first metallization layer and the second metallization layer comprises:
a dielectric layer having an opening aligned with the first region to surround the chip region of the first substrate, wherein the opening successively passes through the first substrate, the first metallization layer, and the second metallization layer; and
a plurality of first metal stacking layers disposed in the dielectric layer and aligned with the first region, wherein at least one of the plurality of first metal stacking layers is aligned with the opening.

24. The chip package as claimed in claim 23, wherein the peripheral region further comprises a second region surrounding the first region, and each of the first metallization layer and the second metallization layer further comprises:
a plurality of second metal stacking layers disposed in the dielectric layer and aligned with the second region, wherein the opening laterally extends onto the second region and is aligned with at least one of the plurality of second metal stacking layers.

25. The chip package as claimed in claim 24, wherein the opening comprises:
an upper portion exposing a bottommost layer surface of the at least one of the plurality of first metal stacking layers and a bottommost layer surface of the at least one of the plurality of second metal stacking layers; and
a lower portion having a V-shaped cross-sectional profile.

26. The chip package as claimed in claim 23, wherein the opening comprises:
an upper portion exposing a bottommost layer surface of the at least one of the plurality of first metal stacking layers and a bottommost layer surface of the at least one of the plurality of second metal stacking layers; and
a lower portion having a V-shaped cross-sectional profile.
